(19) United States
(12) Patent Application Publication
(10) Pub. No.: US 2026/0050021 A1
(43) Pub. Date: Feb. 19, 2026

(54) TEST DEVICE FOR HIGH-FREQUENCY APPLICATIONS

(71) Applicant: INGUN PRUEFMITTELBAU GMBH, Konstanz (DE)

(72) Inventor: Sergiy Royak, Konstanz (DE)

(21) Appl. No.: 19/300,330

(22) Filed: Aug. 14, 2025

(30) Foreign Application Priority Data
Aug. 14, 2024 (DE) 10 2024 123 228.5

(51) Int. Cl. G01R 29/08

(52) U.S. Cl. CPC G01R 29/0878

(57) ABSTRACT

The present invention relates to a test probe (10) for contactless measuring of the electromagnetic properties of a radio unit (20), in particular an antenna unit, the test probe (10) comprising a waveguide (1) for transmitting electromagnetic waves, a filler element (2) made of dielectric material and disposed in the waveguide (1), a lens element (3) for coupling electromagnetic waves into the waveguide (1), the lens element (3) being made of dielectric material and being disposed at one end of the waveguide (1), and a contact portion (4) for coupling out a measurement signal, the contact portion (4) being disposed at an end of the waveguide (1) opposite the lens element (3).

Due to the ongoing technological development of high-frequency applications, the antennas or array antennas installed in base stations and end devices that communicate with them, which operate using the 5G mobile communications standard, for example, are becoming more complex. This opens up new options of application, such as the so-called Massive MIMO (Multiple Input, Multiple Output) method, in which simultaneous signal transmission to multiple end devices with increased data capacity is achieved by interconnecting a plurality of antenna elements of an array antenna, and in which (3D) beamforming additionally enables optimized bundling and alignment of the transmission power to a respective end device. At the same time, however, corresponding devices and systems which enable economical and reliable testing of, for example, an amplitude property or a phase property of wireless antenna elements or array antennas are required for testing such applications.

Antenna elements or array antennas for high-frequency applications of this kind typically do not have test connections, so testing or measurement of the antenna properties has to be carried out using over-the-air (OTA) methods and thus without contact.

Solutions which detect the antenna properties, for example by means of near-field measurement are already known from the prior art. For example, DE 10 2019 215 280 A1 discloses a test probe for testing electronic test objects, such as a dipole antenna, the test probe comprising a sensor disposed on the carrier and having two pin-shaped antennas which are electrically connected and designed to detect a property, in particular an electrical or electromagnetic property, of the test object. The pin-shaped antennas are designed as wire elements or coaxial wires.

WO 2020/103031 A1 discloses a directional probe for broadband measurement of antenna properties, the directional probe comprising a coaxial conductor having an inner conductor, an insulator surrounding the inner conductor, and an outer conductor. A connecting conductor provided at one end extends axially and parallel to a face of the coaxial conductor and connects the inner and outer conductors.

Test solutions which are designed for testing in the far field of the antenna and for direct measurement of the respective field properties are also known. However, they have the disadvantage of a significantly more complex test procedure, in which a test device must be placed at a plurality of different positions in the far field of the antenna to be tested one after the other in a measuring chamber, for example, a corresponding measurement having to be carried out at each of the positions under appropriate control of the antenna.

DE 10 2011 088 171 A1 discloses a method for testing microwave signals from electronic components, wherein a far field of a radiation source in the component to be examined is detected. The microwave signals are received by an antenna device consisting of multiple individual antennas having a specific aperture width. The distance between the antenna device and the electronic component is selected to be greater than 1.5 times the wavelength of the measured microwave signals and less than twice the aperture width. The electric field distribution in the plane of the electronic component is determined by back-calculating the signal propagation to the signal source.

DE 10 2021 117 664 of the applicant discloses a circular waveguide for contactless measuring of the electromagnetic properties of an antenna unit, a filler element made of dielectric material disposed in the waveguide, a lens element for coupling electromagnetic waves into the waveguide, the lens element being disposed at one end of the waveguide, and a contact portion for coupling out a measurement signal, the contact portion being disposed at the end of the waveguide opposite the lens element.

In light of this state of the art, the object of the present invention is to provide an improved test device that enables economical and reliable testing of an antenna element or an array antenna in the context of high-frequency applications. In particular, a device and an associated method for contactless testing or measurement that allow testing an antenna element or an array antenna with regard to its properties and, in particular, with regard to an amplitude property and/or a phase property are to be provided. This object is attained by the test probe, the test device, and the method according to the independent claims. The dependent claims describe advantageous embodiments of the present invention.

In a first aspect, the present invention relates to a test probe for contactless measuring of the electromagnetic properties of a radio unit, in particular an antenna unit, the test probe comprising a waveguide for transmitting electromagnetic waves, a filler element made of dielectric material and disposed in the waveguide, a lens element for coupling electromagnetic waves into the waveguide, the lens element being made of dielectric material and being disposed at one end of the waveguide, and a contact portion for coupling out a measurement signal, the contact portion being disposed at an end of the waveguide opposite the lens element, wherein the waveguide is realized as a cross-shaped waveguide at least in sections.

The present invention enables the provision of a test probe of a simplified design for reliable testing of a respective antenna unit of an array antenna by means of near-field measurement. The test probe can be integrated significantly better into a production process than the far-field measuring devices known from the prior art. The design of the test probe with a cross-shaped waveguide allows a significantly wider frequency range to be detected by the test probe than is the case with the devices known from the prior art. At the same time, a simplified and more compact design with optimized signal evaluation is made possible.

According to the invention, the waveguide of the test probe is realized as a cross-shaped waveguide at least in sections. This means that the waveguide is realized as a cross-shaped waveguide at least partially or at least in a longitudinal portion between the contact portion and the lens element. The waveguide preferably has an essentially cross-shaped cross section at least in sections, preferably a rectangularly cross-shaped cross section. This means that adjacent wall elements of the cross-shaped cross section are essentially perpendicular to each other.

The cross-shaped waveguide design provides significantly optimized transmission characteristics of the test probe compared to a round waveguide. For example, capacitive excitation with an E-field probe is significantly more broadband compared to a round waveguide design. In particular, a broadband transition from coaxial to waveguide is made possible. Furthermore, polarization instability due to angular displacement of the electric field in the waveguide channel, as occurs with a round waveguide, is largely prevented or minimized. Thus, when a rectangular waveguide is provided, electric field propagation occurs only perpendicular to the width of the waveguide cross section. By providing the waveguide as a cross-shaped waveguide and thus two rectangular waveguides disposed perpendicular to each other, two polarized waves can be transmitted. In particular, the transmission of vertically and horizontally polarized TE₁₀ waves is enabled, polarization stability and good cross-polar rejection being achieved.

The test probe is preferably pin-shaped, the waveguide preferably extending axially. The waveguide consists of a highly conductive material, such as copper, aluminum, silver, or gold.

Furthermore, the waveguide advantageously comprises a connecting portion aligned with the lens element and having an essentially round cross section. The round cross section advantageously aids the placement on or the connection with the lens element.

In a preferred embodiment, the waveguide comprises a longitudinal portion which is disposed between the contact portion and a connecting portion aligned with the lens element and in which the cross section of the waveguide preferably transitions continuously from a cross-shaped cross section at the contact portion to a round and/or oval cross section at the connecting portion. In particular, an inwardly directed contour of the cross-shaped cross section preferably merges continuously into a round and/or oval cross-sectional contour in the axial direction of the test probe. It is also advantageous for at least the contact portion of the waveguide to have a cross-shaped cross section.

The contact portion is preferably formed by two rectangular waveguides standing perpendicular to each other. A center of the waveguide preferably remains free of parts of the waveguide contour extending therein.

In a preferred embodiment, the contact portion comprises a first longitudinal portion having a cross-shaped cross section and an end portion extending from the rear thereof and having a rectangular cross section. In the rear end portion, part of the cross-shaped waveguide is advantageously formed as a rectangular waveguide extended in the longitudinal direction. This enables optimized coupling of the measurement signal out of the waveguide. Outcoupling elements, which are described in more detail below, can be arranged in the first and second longitudinal portions in a simple and efficient manner in order to couple out two waves polarized perpendicular to each other in the test probe.

Furthermore, on at least two opposite sides, the rear end portion is advantageously stepped on both sides relative to the outer contour of the first longitudinal portion. In particular, the rectangular waveguide has an increased width relative to the outer contour of the first longitudinal portion or of the cross-shaped waveguide in the first longitudinal portion. This enables further optimized coupling of the measurement signal out of the waveguide. In particular, a TE₁₀ wave can optimally reach a designated outcoupling element in the second longitudinal portion, even without the provision of additional components and/or elements for outcoupling.

Advantageously, the first longitudinal portion outside the rectangular end portion extending therefrom is closed at the rear. Furthermore, the second longitudinal portion is advantageously closed at the rear. This provides a respective short circuit or backshort at which the respective wave is reflected back and can be coupled out of the waveguide at the respective outcoupling element.

In a preferred embodiment, the contact portion comprises two outcoupling elements for outcoupling a wave transported in the waveguide, the outcoupling elements being perpendicular to each other and preferably extending from a side wall in a direction perpendicular to the longitudinal direction of the test probe. The outcoupling elements are offset from each other in the longitudinal direction or in the wave propagation direction. A first outcoupling element is advantageously disposed in the first longitudinal portion of the contact portion, and a second outcoupling element is disposed in the second longitudinal portion of the contact portion.

Furthermore, the outcoupling elements are advantageously realized as a coaxial output. The outcoupling elements are preferably designed for tapping a respective linear polarization. In particular, the outcoupling elements are designed for coupling out a measurement signal for a first, in particular horizontal polarization, and a second, in particular vertical polarization.

The outcoupling elements preferably each comprise a coaxial connector which is disposed on the wall of the waveguide in the contact portion of the test probe. Furthermore, the outcoupling elements preferably each comprise an associated electrical conductor which is disposed in the waveguide in a direction perpendicular to the direction of extension or the wave propagation direction. The electrical contact elements thus advantageously form a type of dipole probe for coupling out the respective measurement signals. A first conductor of the first outcoupling element is preferably designed as a pin or wire and is disposed at an angle of 90° to a second conductor of the second outcoupling element, which is also preferably designed as a pin or wire.

The test probe according to the invention is designed at least for measuring a respective amplitude property of a test object. The test probe is preferably designed for measuring or testing antenna elements or array antennas which emit in the bandwidth range of an NTN (non-terrestrial network) for satellite communication and/or in the bandwidth range of the 5G mobile communication standard, in particular in the range from 17.7 to 30.0 GHz or in the range from 24.25 to 29.5 GHz. The invention is not limited to this frequency range and can also be used for frequencies that differ therefrom, in particular for higher frequencies.

The filler element of the waveguide is preferably made of plastic or ceramic material and preferably extends across the entire length of the waveguide. The filler element can be composed of one or more parts. Preferably, the filler element fills the interior of the waveguide completely. Furthermore, the filler element can have conductors disposed therein or integrally formed therewith.

In a preferred embodiment, the filler element consists of plastic and has a dielectric constant εᵣ of 2.5 to 10, more preferably of 2.8 to 9.7, and even more preferably of 6.5 to 9.7, and even more preferably of 8.0 to 9.2. In a particularly preferred embodiment, the filler element consists of polyether ether ketone (PEEK) with a dielectric constant εᵣ of 3.3. In another particularly preferred embodiment, the filler element consists of Preperm from the manufacturer Premix, for example Preperm PPE800 or Preperm PPE950, which have a dielectric constant εᵣ of 8 and 9.5, respectively.

Alternatively, the filler element may consist of a ceramic material such as aluminum oxide, in particular a multilayer ceramic material, such as High Temperature Cofired Multilayer Ceramic (HTCC) or Low Temperature Cofired Multilayer Ceramic (LTCC). The multilayer ceramic material may have integrally formed conductive elements which are incorporated into the material during manufacture. In this embodiment, the dielectric constant εᵣ is preferably 7 to 10, preferably 7 to 9.5.

The lens element of the test probe is preferably realized as an electrical lens at a tip of the test probe. The lens element preferably protrudes or is configured to protrude from the waveguide in the longitudinal direction of the test probe. The lens element thus protrudes over a front end area at the end of the waveguide. The lens element is preferably made of plastic and has a dielectric constant εᵣ>1. In a preferred embodiment, the lens element is made of plastic and has a dielectric constant εᵣ of 2.5 to 10, more preferably of 2.8 to 9.7, and even more preferably of 6.5 to 9.7.

In a preferred embodiment, the lens element is made of polyether ether ketone (PEEK) with a dielectric constant εᵣ of 3.3. In another preferred embodiment, the lens element is made of Preperm from the manufacturer Premix, for example Preperm PPE800 or Preperm PPE950, which have a dielectric constant εᵣ of 8 and 9.5, respectively. Alternatively, the lens element can be made of ceramic material, analogously to the filler element described above. The lens element is further preferably integral, i.e., formed in one piece, with the filler element or at least a part of the filler element.

The lens element is preferably realized as a stepped lens element and preferably comprises a stepped tip. The lens element preferably has a plane, preferably circular face and at least two, preferably at least three coaxial stepped sections each having an enlarged diameter. Alternatively, the lens element can be realized as an ellipsoid at the tip of the test probe. Advantageously, the lens element can further comprise a centrally disposed electrical conductor at least partially extending in the longitudinal direction of the test probe or of the waveguide. The electrical conductor may in particular be a thin wire extending axially and centrally in the lens element. This optimizes the guidance of the electromagnetic waves in the waveguide and in particular short-circuits the electrical part of the TM₀₁ mode, whereas the propagation of the fundamental mode TE₁₁ is not affected.

The test probe and, in particular, the waveguide are preferably free of additional components or elements disposed therein, such as a polarizer and/or absorber for linear polarization and/or absorption. A corresponding alignment and/or transmission of the waves coupled in through the lens element is already achieved by the fact that the waveguide is realized as a cross-shaped waveguide at least in sections according to the invention. This makes the test probe much easier to construct.

This embodiment of the test probe is preferably designed for measuring a respective amplitude property and/or the phase properties of a test object. In particular, the test probe can be used to measure an amplitude property for both a first and a second polarization. This enables more detailed measurement and testing of a respective test object broken down according to the respective phase property.

In another aspect, the invention relates to a device for testing an array antenna, the device comprising a plurality of test probes as described above, the device having one or more support elements for the respective test probes, which allow disposing each of the test probes in a predefined manner relative to each other, preferably at a mutual distance of λ/2 or λ2/3 of the frequency emitted by the array antenna.

An array antenna is to be understood as an interconnection of individual antenna elements. The distance between the individual antenna elements is determined by the frequency range of the array antenna and is usually λ/2. The antenna elements of the array antenna may be arranged in the shape of a rectangular field. However, the array antenna may also have shapes that deviate therefrom, in particular curved shapes.

The device is preferably designed in such a manner that a respective test probe is disposed directly opposite a respective antenna element in the direction of radiation of the antenna element. The support elements for the test probes can be adjustable, in particular to adapt a respective distance between the test probes and/or the respective spatial alignment of the individual test probes with the test object.

The test device according to the invention enables simultaneous measurement and testing of a plurality of antenna elements of an array antenna with the test probe according to the invention. In addition to direct measurement of a respective antenna element of the array antenna regarding its function, for example a pure check of correct functioning by amplitude measurement or measurement of the field strength, simultaneous testing of the functioning of the array antenna by measurement at multiple measuring points by the individual test probes can also be carried out, on the basis of which, for example, a subsequent near-field-to-far-field calculation can be performed.

In a preferred embodiment, the device comprises an evaluation unit for this purpose, which is connected to the individual test probes of the device and is configured to implement a near-field-to-far-field mapping algorithm. This allows the near-field measurement results of the individual test probes to be calculated or transformed to a far-field based on the measurement results recorded in the near field. The underlying method for such a calculation or such an algorithm is known from the prior art, see for example Antenna Theory, Analysis and Design, Constantine A Balanis; or https://de.mathworks./m/matlabcentral/fileexchange/23385-nf2ff.

In another aspect, the invention relates to a method for contactless measuring, in particular near-field measuring, of the electrical or electromagnetic properties of a radio unit, in particular an antenna unit or an array antenna, wherein the radio unit emits microwave signals and in particular in the bandwidth range of a non-terrestrial network for satellite communication, and wherein the emitted microwave signals are detected by an associated test probe or an associated test device as described above and are evaluated by an associated evaluation unit.

The method may comprise the further step of a near-field-to-far-field calculation or the implementation of a near-field-to-far-field mapping algorithm, as described above in connection with the device according to the invention.

Individual features, other advantageous effects, and details of the present invention are explained below with reference to the schematic, merely exemplary drawings.

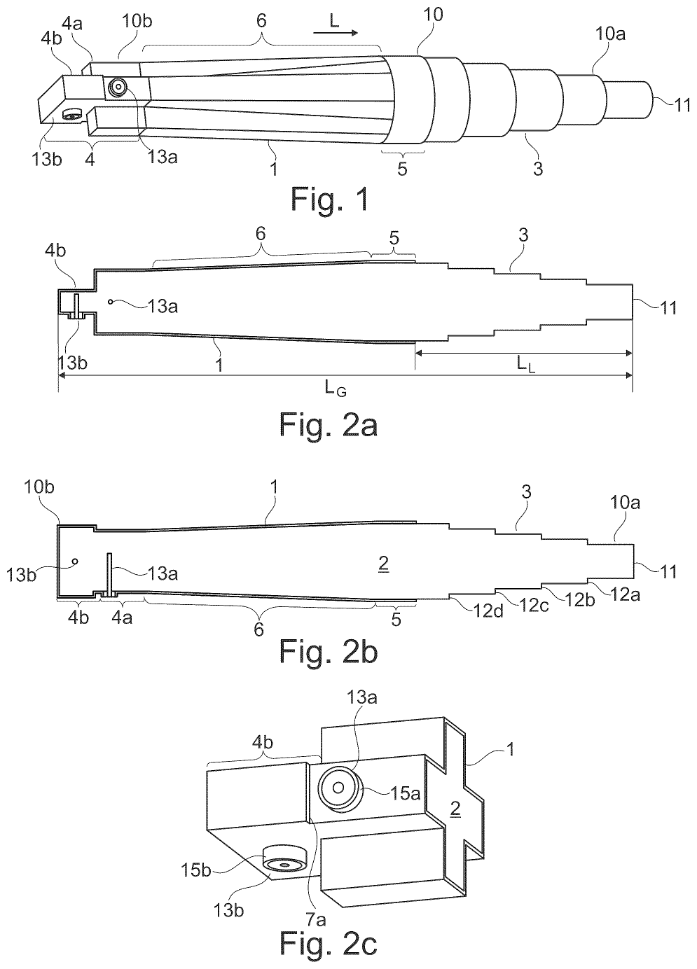

FIG. 1: is a first preferred embodiment of the test probe according to the invention in a perspective side view;

FIGS. 2a, b: are a first and an orthogonal second longitudinal section view of the test probe of FIG. 1;

FIG. 2c: is a cross-sectional view in a rear portion of the test probe of FIG. 1 perpendicular to the longitudinal direction of the test probe;

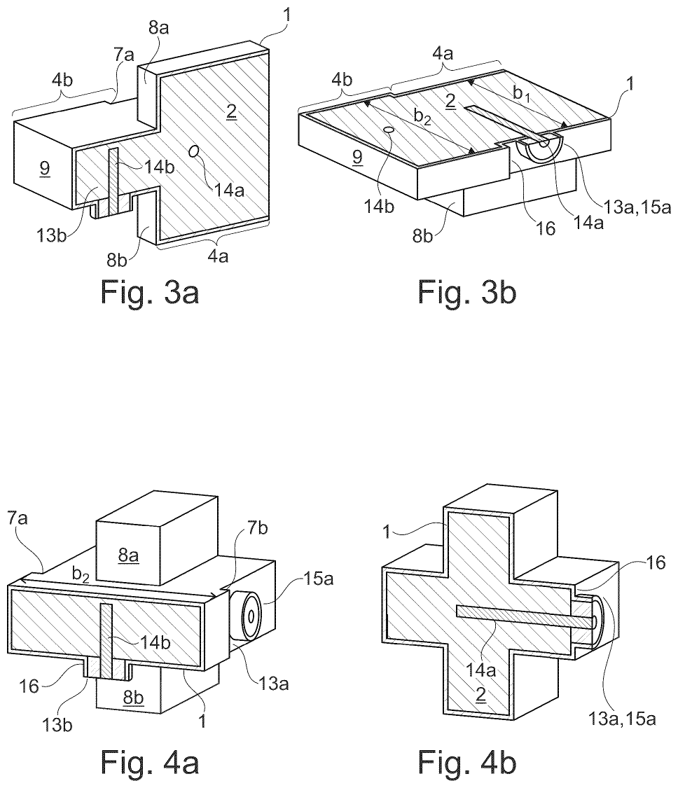

FIGS. 3a, b: are perspective longitudinal section views of the contact of the der test probe of FIG. 1;

FIGS. 4a, b: are perspective cross-sectional views of the contact portion of the test probe of FIG. 1;

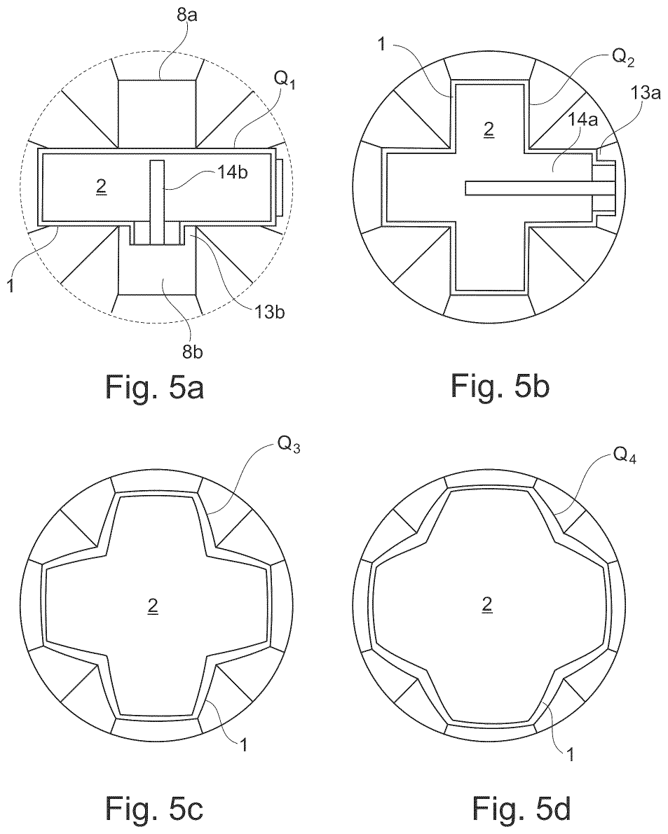

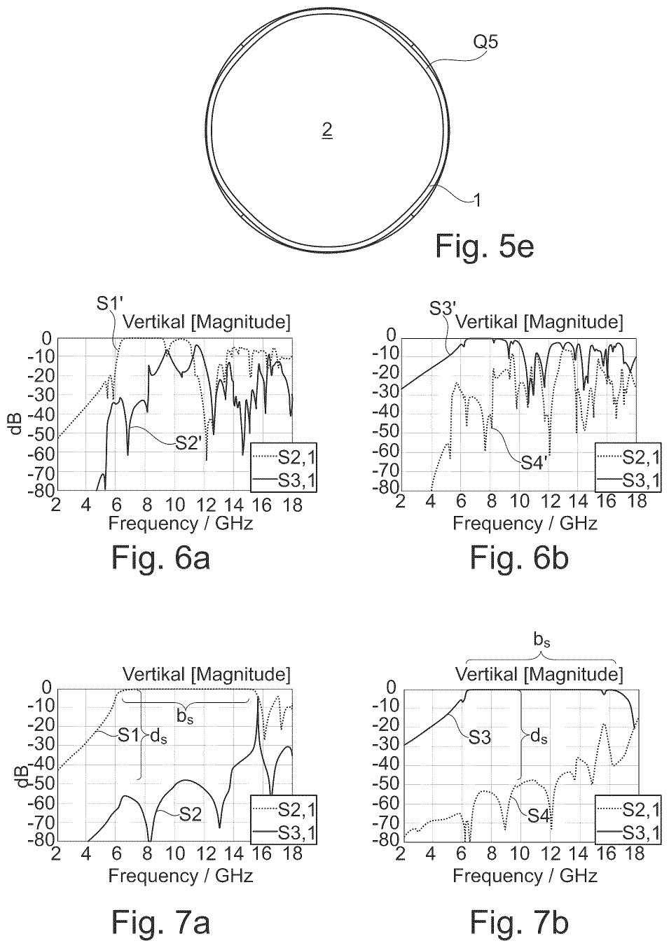

FIGS. 5a-e: are cross-sectional views in different successive positions in the longitudinal direction of the test probe of FIG. 1;

FIGS. 6a, b: show simulation results of a circular waveguide from the prior art;

FIGS. 7a, b: show simulation results of the test probe according to the invention with a cross-shaped waveguide;

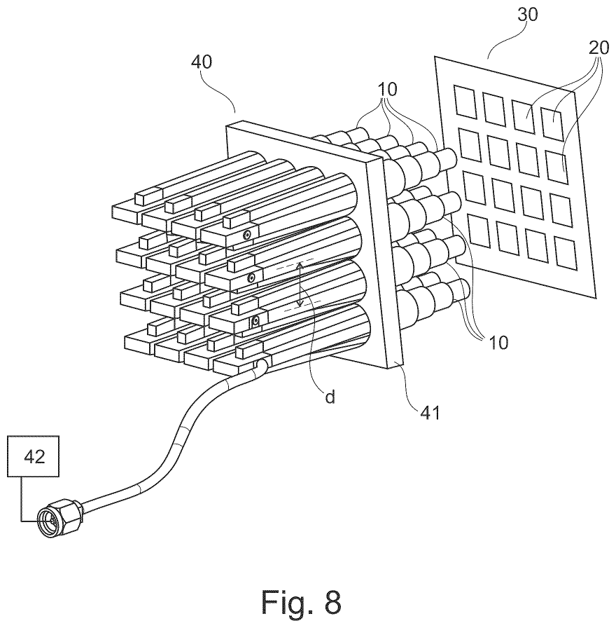

FIG. 8: is a perspective view of a test device according to the invention for measuring an array antenna;

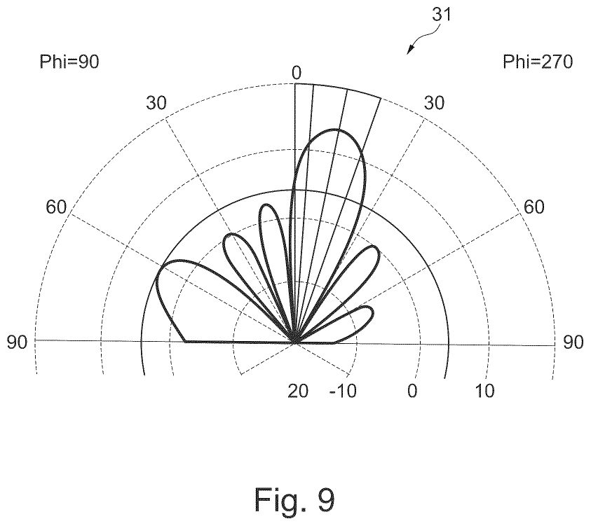

FIG. 9: is an exemplary radiation diagram for assessing the far-field properties of an array antenna, calculated based on the near-field measurement taken by means of the test device according to the invention;

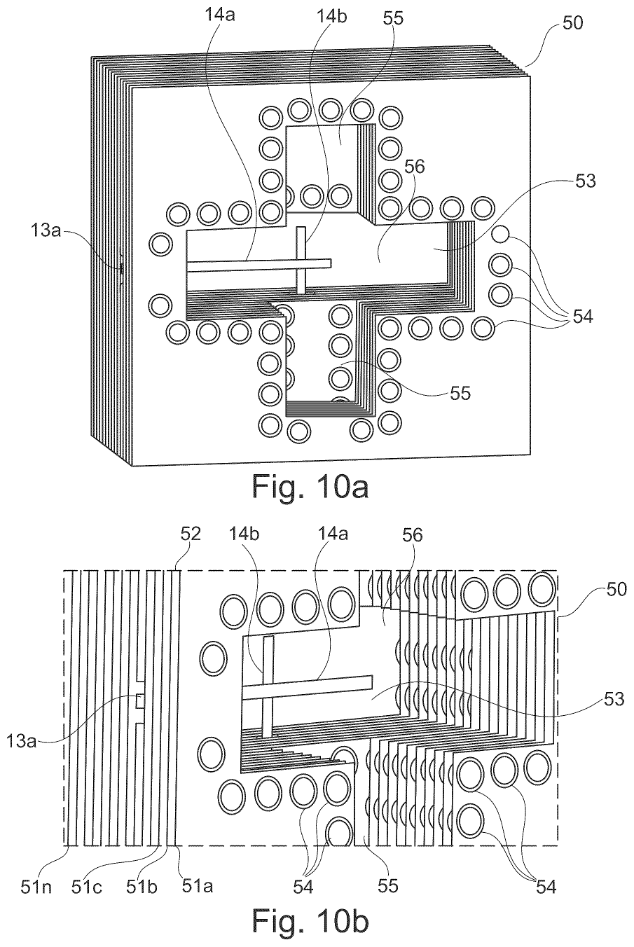

FIGS. 10a, b are perspective plan views of a multilayer printed circuit board for being connected to the test probe; and

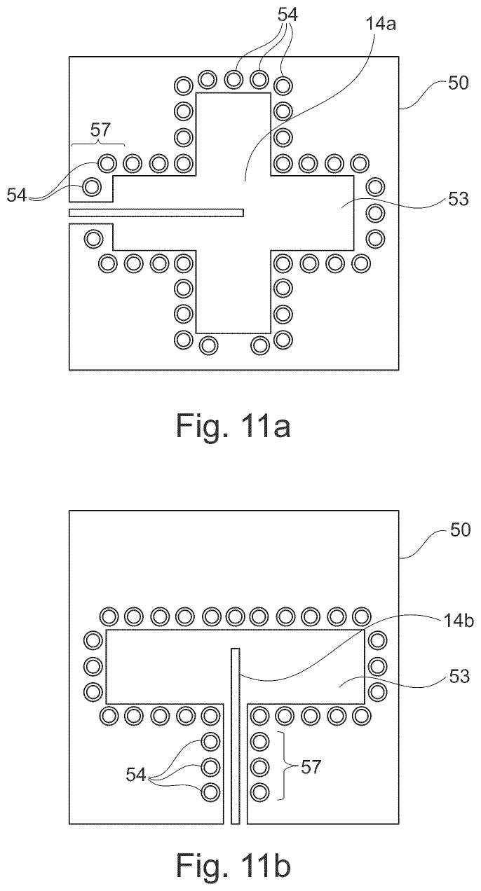

FIGS. 11a, b are sectional views of the printed circuit board of FIGS. 10a, b.

A preferred embodiment of the test probe according to the invention is described below with reference to FIGS. 1 to 5.

The test probe 10 according to the invention comprises a lens element 3 for coupling in electromagnetic waves, the lens element 3 being disposed at a tip of the test probe 10a, a waveguide 2 for transmitting electromagnetic waves, and a contact portion 4 for coupling out a measurement signal, the contact portion 4 being disposed at the rear and in particular at an end 10b of the test probe 10 opposite the lens element 3 or the tip 10a. The test probe 10 is essentially pin-shaped and thus extends axially from the tip 10a to the opposite end 10b, at which the contact portion 4 is formed. A total length L_{G} of the test probe is preferably 30 to 150 mm, more preferably 30 to 120 mm.

A filler element 2 made of dielectric material, for example a plastic, such as PEEK or Preperm PPE, is disposed in the waveguide 1. The filler element 2 preferably extends across the entire length of the waveguide 1 or fills it across its entire length. The cross-sectional shape of the filler element 2 may vary in part. Furthermore, the filler element 2 can be formed in one piece or in multiple pieces.

At least in sections, the waveguide 1 is realized as a cross-shaped waveguide having an essentially cross-shaped cross-sectional shape. The cross-sectional shape of the waveguide may vary at least partially in the longitudinal direction of the waveguide. In this case, the waveguide 1 may in particular have multiple successive sections in the longitudinal direction L with at least partially different cross sections.

The waveguide 1 advantageously comprises a first connecting portion 5 aligned with the lens element 3 and having an essentially round cross section. Furthermore, the waveguide advantageously comprises a second longitudinal portion 6, which is disposed between the contact portion 4 and a connecting portion 5 aligned with the lens element 3. The second longitudinal portion 6 is designed in such a manner that the cross section of the waveguide 1 preferably transitions continuously from a cross-shaped cross section at the contact portion 4 to a round and/or oval cross section at the connecting portion 5.

The lens element 3 is preferably integral or formed in one-piece with the filler element 2 and protrudes from the waveguide 1. The lens element 3 preferably has a lens length L_{L} of 5 to 20 mm, more preferably of 6 to 12 mm, in the longitudinal direction L.

The lens element 3 is advantageously realized as a stepped lens element having a preferably plane face 11 and at least two, preferably three or more coaxial stepped sections 12a to 12d each having a widening diameter. The lens element 3 may comprise a conductor element extending in the longitudinal direction, in particular in the form of a wire (not shown) extending in the longitudinal direction.

The contact portion 4 comprises a first longitudinal portion 4a having a cross-shaped cross section and a second longitudinal portion, in particular an end portion 4b, extending at the rear thereof and having a rectangular cross section. In the rear end portion 4b, part of the cross-shaped waveguide is formed as a rectangular waveguide extended in the longitudinal direction.

The rear end portion 4b is designed in such a manner that, on at least two opposite sides, it is stepped in relation the outer contour of the first longitudinal portion 4a on both sides. In particular, a second width b2 of the end portion 4b is increased relative to a first width of the contour of the first longitudinal portion 4a (see, for example, FIG. 3b). This results in two opposite contour steps 7a, 7b in the waveguide 1.

The first longitudinal portion 4a outside the rectangular end portion 4b extending therefrom is closed at the rear. The longitudinal portion 4a comprises a first and a second rear face wall element 8a, 8b, which closes the cross-shaped waveguide contour at the end.

The second longitudinal portion 4b is also closed at the rear. The longitudinal portion 4b comprises a rear face wall element 9, which closes the rectangular waveguide contour at the end.

The contact portion 4 comprises two outcoupling elements 13a, 13b which are offset from each other in the longitudinal direction and which are designed for tapping or outcoupling a respective wave with linear polarization, in particular a horizontal first polarization and a vertical second polarization.

The outcoupling elements 13a, 13b preferably each comprise an electrical conductor 14a, 14b, which is disposed in the waveguide 1 in a direction perpendicular to the longitudinal direction L and is preferably realized as a pin-like wire. Furthermore, the outcoupling elements 13a, 13b can advantageously each comprise a coaxial plug 15a, 15b, which is disposed on a wall 16 of the waveguide 1 and serves for signal tapping. The electrical conductor 14a, 14b is advantageously contacted with a respective inner conductor of the coaxial plug 15a, 15b.

The contact portion 4 of the test probe 10 enables optimized differentiation between a horizontal first polarization and a vertical second polarization of a detected electromagnetic wave. This makes it possible to measure in particular an amplitude property for both a first and a second polarization. For this purpose, the respective outcoupling elements 13a, 13b are offset from each other by 90° in cross-sectional view, as shown in FIG. 4a, for example.

FIGS. 5a to e show cross-sectional views in different successive positions in the longitudinal direction of the test probe 10. FIG. 5a shows a cross section perpendicular to the longitudinal direction L of the test probe in the area of the second longitudinal portion 4b of the contact portion 4, with an essentially rectangular cross-sectional shape Q1 of the waveguide 1. FIG. 5b shows a cross section in the area of the first longitudinal portion 4a of the contact portion 4 with a cross-shaped cross-sectional shape Q2 of the waveguide 1. FIGS. 5c and 5d show two cross-sectional views in the area of the connecting portion 6 of the waveguide, in which the cross-shaped cross-sectional shape preferably transitions continuously into a rounder or more oval cross-sectional shape Q3, Q4. FIG. 5eshows a cross section in the area of the connecting portion 5, in which the waveguide 1 has a round or approximately round cross-sectional shape Q5.

FIGS. 6a and 6b show simulation results for a round waveguide according to the prior art, while FIGS. 7a and 7b show the corresponding simulation results for the test probe according to the invention for comparison purposes. FIGS. 6a and 7a each show the measured values for a vertical first polarization, and FIGS. 6b and 7b show the measured values for a horizontal second polarization. The respective graphs S1 and S3 represent a first transmission characteristic of the test probe of the vertical and the horizontal polarization, respectively. Graphs S2 and S4 represent a second transmission characteristic of the vertical and the horizontal polarization, respectively.

It can be seen that the solution according to the invention enables significantly more broadband transmission (cf. subarea bS in S1, S3 compared to the prior art according to S1′, S3′) and significantly deeper separation of the vertically and horizontally polarized waves (cf. distance bS of the signal measurements in FIGS. 7a, 7b compared to the prior art).

The test probe 10 can be adapted for a specific high-frequency application depending on the area of application. The dimensions of the waveguide, in particular the diameter of the waveguide, are selected such that it can serve as a waveguide for the transmission of electromagnetic waves for the respective application, in particular for the high-frequency application to be tested in each case.

The test probe 10 according to the invention is used for near-field measurement of a test object. For example, when measuring an antenna element 20 (see FIG. 9), the test probe 10 is positioned in the main radiation direction, preferably axially opposite, in the near field of the antenna element 20 or an array antenna 30 comprising a plurality of antenna elements 20. In the case of an array antenna, the distance between the individual antenna elements 20 is basically determined by the frequency range of the array antenna 30. Said frequency range is usually λ/2.

The device 40 according to the invention for measuring an array antenna 30 now comprises a plurality of test probes 10 as described above, the device 40 having at least one support element 41, shown here only schematically, for the respective test probes 10. The support element 41 is designed to allow a preferred arrangement of the respective test probes 10 relative to each other and/or relative to the respective array antenna 30 or to the individual antenna elements 20 of the array antenna 30.

The support element 41 can be advantageously designed in such a manner that a predefined arrangement of the test probes 10 relative to each other, preferably at a distance d of λ/2 or λ2/3 of the frequency emitted by the array antenna 30, is made possible. The device according to the invention additionally comprises an evaluation unit 42 connected to the respective probes 10 and shown only schematically, the evaluation unit 42 being configured to implement a near-field-to-far-field mapping algorithm for calculating or transforming the near-field measurement results to a far field. For simplicity, only a signal line between a test probe 10 and the evaluation unit 42 is shown here.

When testing an array antenna 30, the signal transmission from the array antenna to each individual probe 10 now serves as the measured variable. The measurement can be performed, for example, with a known network analyzer, and the data can be stored as S parameters and further processed. Ideally, both the horizontal and the vertical polarization are separately fed to a respective coaxial output in each probe 10 and transmitted to the evaluation unit 42 for signal evaluation.

Based on the measurement results of the individual test probes 10 acquired in the near field, the near-field measurement results can then be calculated or transformed to a far field. An example result for such an evaluation is shown in FIG. 9, which shows a one-dimensional radiation diagram 31 of the array antenna 30.

A measurement of the array antenna 30 can take place independently of the exact assignment of the individual test probes 10 to the antenna elements 20 of the array antenna 30. This allows the characteristics of an array antenna 30 having 1×2 or 2×2 antenna elements 20 to be detected, analyzed, and/or subjected to a near-field-to-far-field transformation using a test device 40 or a probe array having 4×4 test probes 10, for example.

The individual test probes 10 of the test device 40 can also be directly assigned to the antenna elements 20 of the array antenna 30, which enables even more accurate testing. The precise assignment allows individual antenna elements 20 to be tested directly and, in particular, defective antenna elements to be detected immediately.

FIGS. 10a, b and FIGS. 11a, b show a preferred embodiment of a multilayer printed circuit board 50 for connecting one or more test probes 10. The multilayer printed circuit board 50 is designed to be arranged on the contact portion 4 of a respective test probe 10. The individual layers 51a, . . . n of the multilayer printed circuit board 50 extend parallel to each other and essentially perpendicular to the longitudinal direction L of the test probe 10. The layers 51a, . . . n comprise conductor tracks for electrical contacting of the test probe 10 and a device, such as a test and/or evaluation unit 42 (see FIG. 8), connected to the multilayer printed circuit board 50.

The multilayer printed circuit board 50 comprises a cutout 53 which is adapted to the contact portion 4 of the test probe 10. In plan view, the cutout 53 is essentially cross-shaped and thus designed to receive the cross-shaped waveguide 1 of the test probe 10. Furthermore, the cutout 53 forms a step 55 on both sides and a deeper bottom area 56 between them, which are designed to come into contact with or close a respective rear area of the test probe 10 at the contact portion 4, in particular to come into contact with or replace the face wall elements 8a, 8b, and 9 of the contact portion 4 of the test probe 10.

Vias 54 are advantageously disposed around the cutout or recess 53. Copper layers are advantageously recessed or etched in the individual layers. Advantageously, respective insulation layers 52 are disposed between the individual layers. Insulation between the layers and/or the conductor tracks of the individual layers is preferably provided by means of an insulating material having the same or at least a similar dielectric constant εᵣ as the filler element 2 of the test probe 10. If the dielectric constant εᵣ of the printed circuit board or of the insulating material is smaller, the geometry of the recess 53 is designed to be larger.

The multilayer printed circuit board 50 is advantageously designed for being connected to the outcoupling elements 13a, 13b of the test probe 10. The electrical conductors 14a, 14b for coupling the signals out of the test probe 10 can be designed as an integral part of the multilayer printed circuit board 50.

The multilayer printed circuit board 50 can advantageously already have circuits for signal processing. The layers 51a, . . . n or the conductor tracks comprising them can form circuits for multiplexing and/or signal processing. As shown in the sectional views in FIGS. 11a, 11b, the vias 54 in the area where the electrical conductors 14a, 14b exit from the multilayer printed circuit board 50 are designed as corresponding shielding, analogously to the provision of a coaxial connector 51a, . . . b.

The embodiments described above are merely examples, and the invention is by no means limited to the embodiments shown in the Figures.

### REFERENCE SIGNS

1 waveguide
2 filler element
3 lens element
4 contact portion
4a first longitudinal portion
4b second longitudinal portion
5 connecting portion
6 longitudinal portion
7a, b contour steps
8a, b face wall elements
9 face wall element
10 test probe
10a test probe tip
10b opposite test probe end
11 plane lens face
12a-d lens step portions
13a, b outcoupling elements
14a, b electrical conductor
15a, b coaxial connector
16 waveguide wall
20 antenna element
30 array antenna
31 radiation diagram
40 test device
41 support element
42 evaluation unit
50 multilayer printed circuit board
51a, . . . n layers
52 insulation layer
53 cutout
54 vias
55 step
56 bottom area
L longitudinal direction
L_{G} total length
L_{L} lens length
bS signal broadband
dS signal distance
d distance

1. A test probe (10) for contactless measuring of the electromagnetic properties of a radio unit (20), in particular an antenna unit, the test probe comprising
a waveguide (1) for transmitting electromagnetic waves, a filler element (2) made of dielectric material and disposed in the waveguide (1),
a lens element (3) for coupling electromagnetic waves into the waveguide (1), the lens element (3) being made of dielectric material and being disposed at one end of the waveguide (1), and
a contact portion (4) for coupling out a measurement signal, the contact portion (4) being disposed at an end of the waveguide (1) opposite the lens element (3), characterized in that the waveguide (1) is realized as a cross-shaped waveguide at least in sections.

2. The test probe according to claim 1, characterized in that the waveguide (1) has an essentially cross-shaped cross section, preferably a rectangularly cross-shaped cross section, at least in sections.

3. The test probe according to claim 1 or 2, characterized in that the waveguide has a connecting portion (5) aligned with the lens element (3), the connecting portion (5) having an essentially round cross section.

4. The test probe according to any one of the preceding claims, characterized in that the waveguide (1) comprises a longitudinal portion (6) which is disposed between the contact portion (4) and the connecting portion (5) aligned with the lens element (3) and in which the cross section of the waveguide (1) preferably transitions continuously from a cross-shaped cross section at the contact portion (4) to a round and/or oval cross section at the connecting portion (5).

5. The test probe according to any one of the preceding claims, characterized in that the contact portion (4) of the waveguide has a cross-shaped cross section.

6. The test probe according to any one of the preceding claims, characterized in that the contact portion (4) is formed by two rectangular waveguides standing perpendicular to each other.

7. The test probe according to any one of the preceding claims, characterized in that the contact portion (4) comprises a first longitudinal portion (4a) having a cross-shaped cross section and an end portion (4b) extending from the rear thereof and having a rectangular cross section.

8. The test probe according to claim 7, characterized in that in the rear end portion (4b), part of the cross-shaped waveguide is formed as a rectangular waveguide extended in the longitudinal direction.

9. The test probe according to claim 7 or 8, characterized in that on at least two opposite sides, the rear end portion (4b) is stepped on both sides relative to the outer contour of the first longitudinal portion (4a).

10. The test probe according to any one of claims 7 to 9, characterized in that the first longitudinal portion (4a) outside the rectangular end portion (4b) extending therefrom is closed at the rear.

11. The test probe according to any one of claims 7 to 10, characterized in that the second longitudinal portion (4b) is closed at the rear.

12. The test probe according to any one of the preceding claims, characterized in that the contact portion (4) comprises two outcoupling elements (13a, 13b) for coupling out a wave transported in the waveguide (1), the outcoupling elements (13a, 13b) being perpendicular to each other and preferably extending from a side wall in a direction perpendicular to the longitudinal direction of the test probe, a first outcoupling element (13a) being disposed in a first longitudinal portion (4a) of the contact portion (4), and a second outcoupling element (13b) being disposed in the second longitudinal portion (4b) of the contact portion (4).

13. The test probe according to claim 12, characterized in that the outcoupling elements (13a, 13b) comprise an electrical conductor (14a, 14b) protruding into the contact portion (4) of the waveguide (1) and a coaxial connector (15a, 15b) connected thereto, the coaxial connector (15a, 15b) being disposed in the wall of the waveguide (1) and being configured to couple the measurement signal out of the test probe (10).

14. The test probe according to any one of the preceding claims, characterized in that the filler element (2) of the waveguide is made of plastic or ceramic material and preferably extends across the entire length (L) of the waveguide.

15. The test probe according to any one of the preceding claims, characterized in that the lens element (3) protrudes from the waveguide (1) in the longitudinal direction (L) of the test probe (10).

16. The test probe according to any one of the preceding claims, characterized in that the lens element (3) is a stepped lens element comprising a preferably plane face (11) and at least two coaxial step portions (12a, 12b) each having a widening diameter.

17. A device (40) for testing an array antenna (30), the device comprising a plurality of test probes (10) according to any one of the preceding claims, the device having at least one support element (41) for the test probes (10) which allows arranging each of the test probes (10) in a predefined manner relative to each other, preferably at a distance (d) of λ/2 or λ2/3 of the frequency emitted by the array antenna (30).

18. The device according to claim 17, wherein the device (40) comprises an evaluation unit (42) connected to the test probes (10) and configured to implement a near-field-to-far-field mapping algorithm for calculating or transforming the near-field measurement results to a far field.

19. A method for contactless measuring, in particular near-field measuring, of the electrical or electromagnetic properties of a radio unit (20, 30), in particular an antenna unit or an array antenna, wherein the radio unit emits microwave signals and in particular in the bandwidth range of a non-terrestrial network for satellite communication, and wherein the emitted microwave signals are detected by an assigned test probe (10) according to any one of claims 1 to 16 or by a test device (40) according to any one of claims 17 or 18 and evaluated by an assigned evaluation unit (42).
